(19) United States
(12) Patent Application Publication
(10) Pub. No.: US 2023/0272987 A1
(43) Pub. Date: Aug. 31, 2023

(54) HEAT SINK ARRAY AND METHOD OF USE

(71) Applicant: NATIONAL UNIVERSITY OF SINGAPORE, Singapore (SG)

(72) Inventors: Poh Seng LEE, Singapore (SG); Shi ZENG, Singapore (SG)

(73) Assignee: NATIONAL UNIVERSITY OF SINGAPORE, Singapore (SG)

(21) Appl. No.: 18/003,405

(22) PCT Filed: Feb. 3, 2021
(86) PCT No.: PCT/SG2021/050056

§ 371 Date: Dec. 27, 2022

(30) Foreign Application Priority Data
Jun. 25, 2020 (SG) 10202006107T

(51) Int. Cl. F28F 13/12; F28F 1/12

(52) U.S. Cl. CPC F28F 13/12; F28F 1/12

(57) ABSTRACT

A heat transfer device includes at least one channel including an upstream zone, a downstream zone, and a mixing zone intermediate the upstream and downstream zones. The upstream zone includes an upstream separating configuration arranged to separate an inflow to the upstream zone into a plurality of upstream sub-flows. The mixing zone includes a converging configuration arranged to converge at least two upstream sub-flows into the mixing zone to form a primary mixed flow.

### FIELD OF THE INVENTION

The invention relates to a fin array of a heat transfer device. In particular, the invention can be used in various high heat flux cooling conditions.

### BACKGROUND

The most common heat sink fin design is the straight fin. Its low heat transfer efficiency and high pressure drop characteristics leave space of improvement in fin design. Pin fin, offset strip fin, step fin and oblique fin are examples of relatively improved designs. However, their cooling performance is only slightly better than that of the straight fin.

Therefore, there is a need for an improved heat sink design.

### SUMMARY OF THE INVENTION

The invention provides a heat transfer device with an improved fin array that outperforms the existing fin designs.

In a first aspect of the invention, there is provided a heat transfer device comprising: at least one channel including an upstream zone, a downstream zone, and a mixing zone intermediate the upstream and downstream zones; the upstream zone including an upstream separating configuration arranged to separate an inflow to the upstream zone into a plurality of upstream sub-flows; and the mixing zone including a converging configuration arranged to converge at least two upstream sub-flows into the mixing zone to form a primary mixed flow. A separating configuration separates fluid into sub-flows by changing the flow direction of at least one sub-flow. The heat sink device arrangement enables effective flow mixing, thus allowing the fin to reach lower average junction temperature than straight channels at the same pumping power. Therefore, heat transfer is more efficient with the improved heat sink device. The channel may contain any number of separating configurations between two converging configurations.

In an embodiment, the upstream separating configuration may include an upstream separating fin arranged to separate the inflow to the upstream zone into first and second upstream sub-flows. The smooth edges of the separating fin reduce resistance and promote smooth fluid flow. The non-continuous fin pattern prevents thick boundary layers from forming. A small vortex forms at the trailing edge of each fin to further enhance heat transfer. The fin may have 2 pairs of parallel walls, such as a parallelogram.

In an embodiment, the downstream zone may include a downstream separating configuration arranged to separate the primary mixed flow into a plurality of downstream sub-flows. This feature enables the starting process (converging sub-flows in the mixing zone) to be repeated through the heat transfer device, while maintaining efficient heat transfer throughout the device.

In an embodiment, the downstream separating configuration may include a downstream separating fin arranged to separate the primary mixed flow into first and second downstream sub-flows. Similar to the upstream separating fin, the downstream separating fin enables smooth fluid flow and prevents thick boundary layers from forming, and thus efficient heat transfer.

In an embodiment, the converging configuration may be continuous with a wall of the channel to mix all upstream sub-flows into the primary mixed flow.

In an embodiment, the separating configuration may be spatially offset from a converging fin of the converging configuration. Similar to the separating fins, the converging fin enables smooth fluid flow and prevents a thick boundary layer from forming, and thus efficient heat transfer. A converging fin may have a pair of parallel sides, such as a trapezoid.

In an embodiment, the heat transfer may further comprise a diverting configuration immediate the upstream or downstream separating configuration and the converging configuration, wherein the diverting configuration is arranged to divert one upstream sub-flow to mix with another upstream sub-flow to form a secondary mixed flow. A diverting configuration may be arranged to divert one sub-flow to mix with another sub-flow to form a secondary mixed flow. To this end, a diverting configuration is a special case of the separating configuration, in that a separating configuration may be a diverting configuration if it changes the direction of two sub-flows.

The diverting configuration may also separate fluid into sub-flows, but differs from a separating configuration in that it changes the direction of both sub-flows. The diverting configuration further enhances fluid mixing, so that the heat transfer is more evenly distributed. Since there are small vortexes at the trailing edges of fins that have a higher temperature than the rest of the fluid, these small pockets of fluid can be redistributed at the secondary mixed flow. A channel may contain any number of diverting configurations between two converging configurations, or between a converging configuration and a separating configuration.

In an embodiment, the diverting configuration may comprise a diverting fin spatially offset from the converging configuration and/or the separating configuration. The diverting fin may have 2 pairs of parallel sides, such as a parallelogram. The diverting fin may be of the same shape as the separating fin to facilitate cutting of the fins during manufacture.

In a second aspect, the present invention provides a method of heat transfer comprising: providing a heat transfer device containing at least one channel including an upstream zone, a downstream zone, and a mixing zone intermediate the upstream and downstream zones; separating an inflow to the upstream zone into a plurality of upstream sub-flows; and converging at least two upstream sub-flows into the mixing zone to form a primary mixed flow. As explained above for the device, this heat transfer method enables effective mixing of the heat transfer fluid and more even distribution of heat compared to conventional heat transfer devices.

In an embodiment, the method may further comprise separating the primary mixed flow into a plurality of downstream sub-flows. This step allows the sub-flows to converge and separate repeatedly through the heat transfer device, while maintaining even mixing of the fluid.

In an embodiment, the method may further comprise diverting one sub-flow to mix with another sub-flow to form a secondary mixed flow. Since there are small vortexes at the trailing edges of fins that have a higher temperature than the rest of the fluid, these small pockets of fluid can be redistributed at the secondary mixed flow.

### BRIEF DESCRIPTION OF THE DRAWINGS

It will be convenient to further describe the present invention with respect to the accompanying drawings that illustrate possible arrangements of the invention. Other arrangements of the invention are possible and consequently, the particularity of the accompanying drawings is not to be understood as superseding the generality of the preceding description of the invention.

FIGS. 1(a) to (c) are schematic diagrams of the oblique-trapezoidal fin arrays of the present invention. FIG. 1(a) shows a concept of the new oblique-trapezoidal fin array. FIG. 1(b) shows flow of the heat transfer fluid through a channel of the improved heat transfer device. FIG. 1(c) shows flow of the heat transfer fluid through a channel of another improved heat transfer device.

FIGS. 2(a) to (c) are schematic diagrams showing 3 possible configurations: (a) 3 oblique fins configuration; (b) 2 oblique fins configuration; and (c) 1 oblique fin configuration

FIGS. 3(a) to (d) are schematic diagrams showing the flow fields of heat sink designs: (a) straight channel; and (b) to (d) 1 oblique fin configuration.

FIGS. 4(a) to (c) are schematic diagrams showing local flow field within one period of fin structures: (a) velocity contours at different locations along the flow direction (x-axis direction away from the channel inlet position, unit: mm); (b) streamlines at the cross section of x=7.75 mm; and (c) streamlines at the cross section of x=10.45 mm.

FIGS. 5(a) to (c) are schematic diagrams showing temperature contour of (a) straight channel; (b) the new fin design; and (c) velocity vectors around the trailing edge of a fin.

FIGS. 6(a) to (d) are schematic diagrams of design geometries: (a) oblique fin, (b) pin fin, (c) offset strip fin, and (d) step fin.

FIG. 7 is a graph of average junction temperatures under various pumping powers for different fin designs: new fin design (NFD), offset strip fin (OSF), pin fin (PF), step fin (SF), oblique fin (OB), and straight channel (SC).

### DETAILED DESCRIPTION

This invention discloses a novel heat sink fin array, which efficiently enhances heat transfer of heat sinks. It could be used in heat sink or cold plate designs for high heat flux heat sources. CPU or GPU is the most potential component that could use the design. As the chip packaging becomes smaller and the power consumption becomes higher, its heat flux grows quickly and is about to exceed the cooling capability of ordinary designs. The new fin design could solve higher heat flux cooling problems due to its enhanced heat transfer capability. Under the same heat flux, it could cool the chip to a lower temperature, which is beneficial to the safety and lifetime of chip operation. In addition, pumping power could be saved. This is an important advantage especially for data center operation as there could be hundreds of cold plates.

Laser is another example that could use our new fin design. As a semiconductor component, its working efficiency and life time is highly dependent on its temperature. With the new fin design, lasers could work under lower temperature, which contributes to better performance.

This invention presents a new fin array that is suitable for heat sinks. The new fin array is composed of two types of fins, oblique fin and trapezoidal fin.

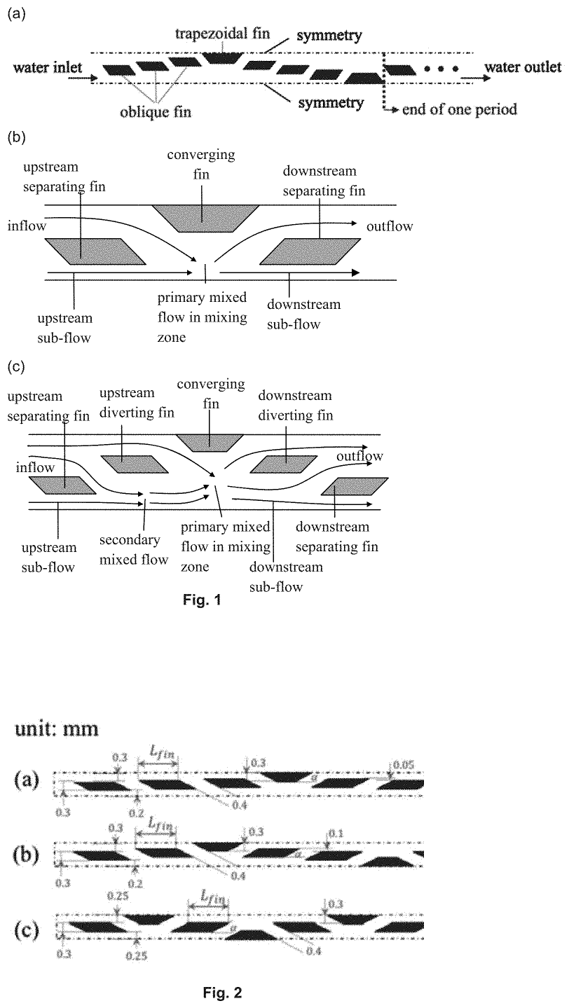

FIG. 1(a) shows a concept of the new oblique-trapezoidal fin array. The fins are laid in a semi-wavy manner with the two trapezoidal fins as the turning point. Oblique fins are offset in the span-wise direction. After the first trapezoidal fin, the oblique fin angle and offset direction are reversed. Another trapezoidal fin lies at the end of one period. Repeating this pattern in the stream-wise direction forms the heat sink structure of one single strip. Then a full heat sink could be obtained by flipping this single strip multiple times about both sides.

FIG. 1(b) shows flow of the heat transfer fluid through a channel of the improved heat transfer device. The inflow is separated into upstream sub-flows by an upstream separating configuration, such as an upstream separating fin as shown. A converging configuration, such as a converging fin, mixes the sub-flows at the mixing zone to form a primary mixed flow. A downstream separating configuration, such as a downstream separating fin, separates the mixed flow into downstream sub-flows.

FIG. 1(c) shows flow of the heat transfer fluid through a channel of another improved heat transfer device. This embodiment contains an upstream diverting configuration, such as a diverting fin. The upstream diverting configuration diverts a sub-flow to mix with another sub-flow to form a secondary mixed flow, which occurs outside the mixing zone. A downstream diverting configuration, such as a downstream diverting fin, diverts a mixed flow to separation by a downstream separating fin. The diverting fins are offset from the converging configurations and separating configurations for this purpose.

The number of oblique fins in each half period could vary. Three examples of the new fin array are shown in FIG. 2: (a) 3 oblique fins configuration; (b) 2 oblique fins configuration; (c) 1 oblique fin configuration. It is appreciated that dimension parameters are to be adjusted for every application.

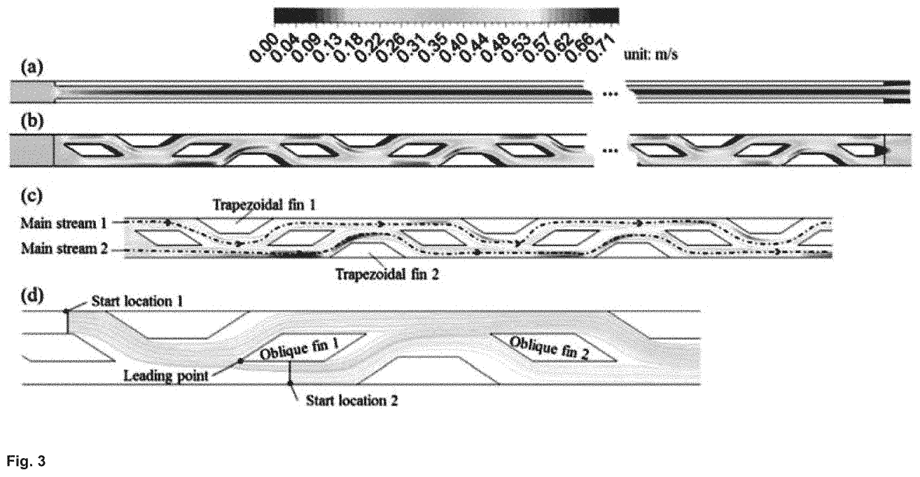

Detailed numerical analysis has been implemented on this new fin design. FIG. 3 shows the flow fields of three different configurations: (a) velocity contour of straight channels (SC); (b) velocity contour of the new fin design; (c) streamlines in a part of the new fin design; (d) local streamlines in the new fin design. FIG. 3 (a) indicates that the velocity contour in SC becomes fully developed soon after entering the micro-channel domain. As shown in FIG. 3 (b), instead of having a continuous wall from the inlet to the outlet, the channel domain of the new fin design is divided into multiple cross-connected regions, hindering the growth of boundary layers. FIG. 3 (c) shows the main streams of water flow inside the new fin design. In each single strip with symmetry boundary conditions on both sides, there are two main streams separated by the oblique fins. Each main stream bends when it encounters trapezoidal fins, creating a semi-wavy flow.

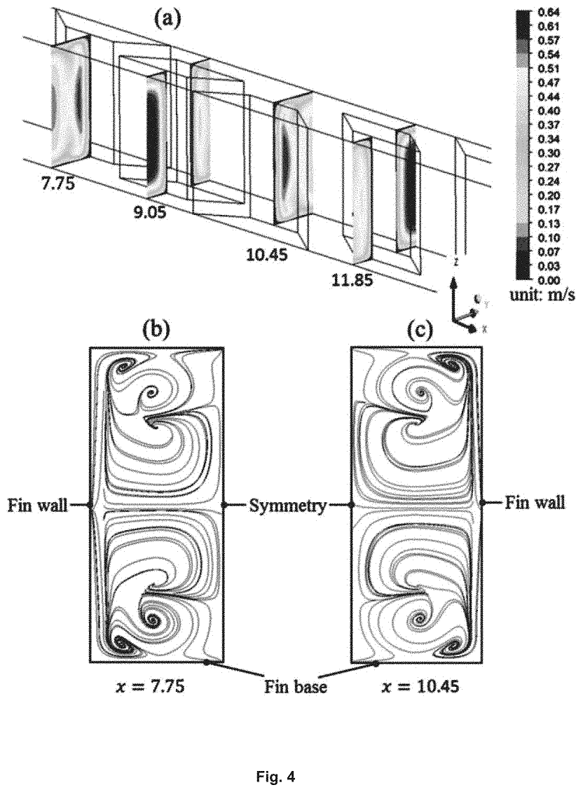

Because of the stagger layout of trapezoidal fins, the two main streams bend toward each other, promoting flow mixing. In addition, the bends creates nonconventional velocity fields and semi-Dean vortices, as shown in FIG. 4.

FIG. 4 shows the local flow field within one period of fin structures: (a) velocity contours at different locations along the flow direction (x-axis direction away from the channel inlet position, unit: mm); (b) streamlines at the cross section of x=7.75 mm; (c) streamlines at the cross section of x=10.45 mm. Though the bend around trapezoidal fin does not result in exactly the same Dean vortices pattern, it could still promote flow mixing in the height direction.

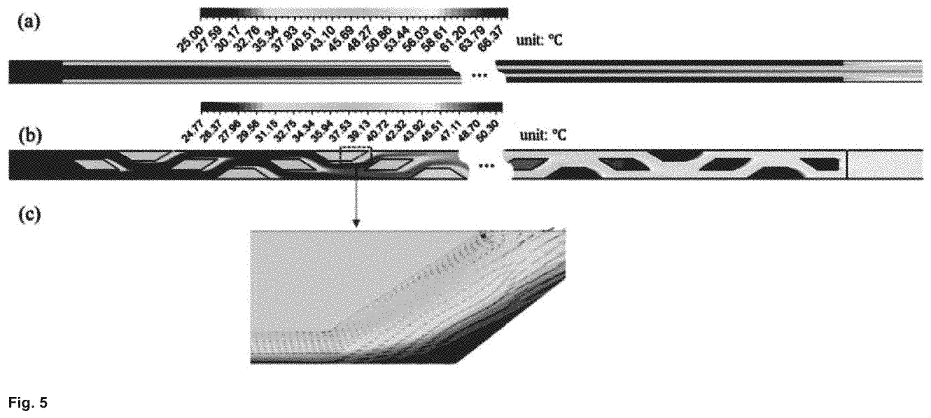

FIG. 5 shows the temperature contour of (a) SC, (b) the new fin design, and (c) velocity vectors around the trailing edge of a fin. In the SC heat sink, fluid in the vicinity of fin walls is firstly heated and heat is transferred to the middle of channel through conduction and advection. Obvious temperature gradient with high temperature at the vicinity of fin walls and low temperature at the middle of channel exits. On the contrary, fluid temperature in the new fin design is rather uniform in the channel transverse direction. As shown in FIG. 5 (b), only a small fluid domain around the trailing edge of fins has an obvious higher temperature than the main channel. This is due to a small vortex at the backside of each fin. This feature leaves opportunity for further heat transfer enhancement of the new fin design. On the other hand, comparing the temperature of fins, the maximum temperature in the new fin design is about 50.30° C. while it is 66.37° C. for the SC. The temperature difference is 16° C., proving the superior heat transfer performance of the new fin design.

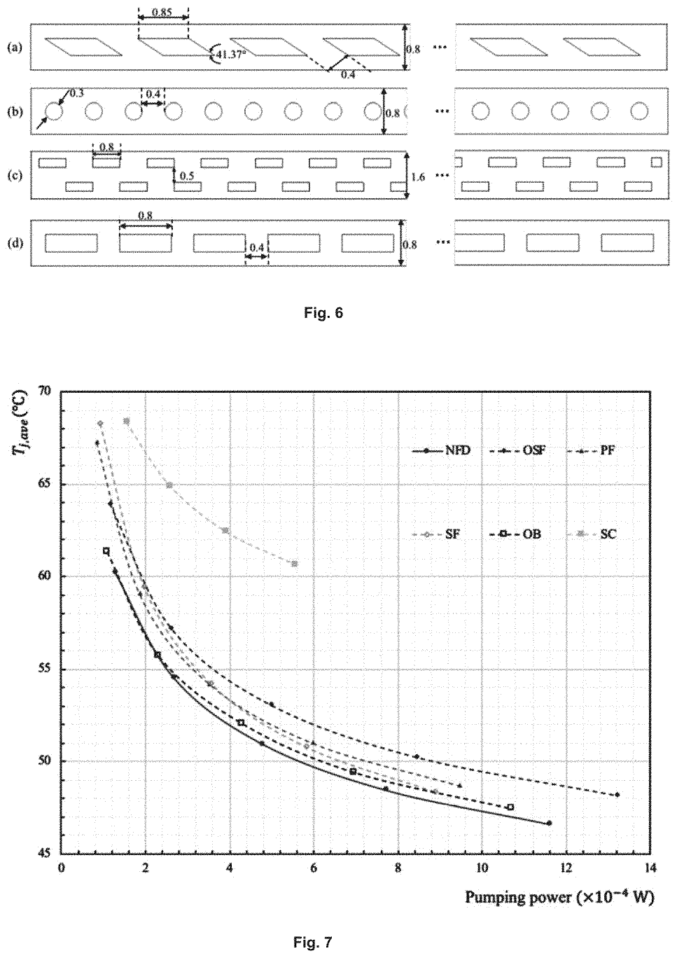

To further verify the effectiveness of the new fin design, it is compared with several other commonly used heat sink designs: conventional straight channel (SC); oblique fin (OB); pin fin (PF); offset strip fin (OSF); Step fin (SF). FIG. 6 shows the geometries of these benchmark designs (a) oblique fin, (b) pin fin, (c) offset strip fin, and (d) step fin.

Their performance is compared in a graph of the average junction temperature versus pumping power (FIG. 7).

It is obvious that the cooling performance of the SC design is limited and much worse than the new fin design. For example, at the pumping power of 5.6e-4 W, the average junction temperature of the SC design is 60.5° C., while it is 50° C. for the new fin design. The temperature improvement is 10.5° C. When compared with other designs, the new fin design could still maintain the lowest average junction temperature by consuming the same pumping power or require the least pumping power when achieving the same average junction temperature. For example, if the average junction temperature is 48.46° C., the new fin design will consume 7.7e-4 W, while the lowest pumping power for all the other designs is around 8.6e-4 W, which is given by the oblique fin. This leads to a pumping power saving of 10.5%.

1. A heat transfer device comprising:
at least one channel including an upstream zone, a downstream zone, and a mixing zone intermediate the upstream and downstream zones;
the upstream zone including an upstream separating configuration arranged to separate an inflow to the upstream zone into a plurality of upstream sub-flows; and
the mixing zone including a converging configuration arranged to converge at least two upstream sub-flows into the mixing zone to form a primary mixed flow.

2. The heat transfer device according to claim 1, wherein the upstream separating configuration includes an upstream separating fin arranged to separate the inflow to the upstream zone into first and second upstream sub-flows.

3. The heat transfer device according to claim 1, wherein the downstream zone includes a downstream separating configuration arranged to separate the primary mixed flow into a plurality of downstream sub-flows.

4. The heat transfer device according to claim 3, wherein the downstream separating configuration includes a downstream separating fin arranged to separate the primary mixed flow into first and second downstream sub-flows.

5. The heat transfer device according to claim 1, wherein the converging configuration is continuous with a wall of the channel to mix all upstream sub-flows into the primary mixed flow.

6. The heat transfer device according to claim 1, wherein the separating configuration is spatially offset from a converging fin of the converging configuration.

7. The heat transfer device according to claim 1, further comprising a diverting configuration immediate the upstream or downstream separating configuration and the converging configuration.

8. The heat transfer device according to claim 7, wherein the diverting configuration comprises a diverting fin spatially offset from the converging configuration and/or the separating configuration.

9. A method of heat transfer comprising:
providing a heat transfer device containing at least one channel including an upstream zone, a downstream zone, and a mixing zone intermediate the upstream and downstream zones;
separating an inflow to the upstream zone into a plurality of upstream sub-flows; and
converging at least two upstream sub-flows into the mixing zone to form a primary mixed flow.

10. The method according to claim 9, further comprising separating the primary mixed flow into a plurality of downstream sub-flows,

11. The method according to claim 9, further comprising diverting one sub-flow to mix with another sub-flow to form a secondary mixed flow.
